(19) United States
(12) Patent Application Publication
(10) Pub. No.: US 2026/0143689 A1
(43) Pub. Date: May 21, 2026

(54) SEMICONDUCTOR STRUCTURE INCLUDING A BIT LINE STRUCTURE AND METHOD OF MANUFACTURING THE SAME

(71) Applicant: NANYA TECHNOLOGY CORPORATION, NEW TAIPEI CITY (TW)

(72) Inventors: YU-JIE JIANG, NEW TAIPEI CITY (TW); TSENG-FU LU, NEW TAIPEI CITY (TW); JHEN-YU TSAI, NEW TAIPEI CITY (TW)

(21) Appl. No.: 18/948,790

(22) Filed: Nov. 15, 2024

(51) Int. Cl. H10B 12/00

(52) U.S. Cl. CPC H10B 12/485; H10B 12/0335

(57) ABSTRACT

A semiconductor structure and a method of manufacturing the same are provided. The semiconductor structure includes a base structure, a bit line structure and a cell contact structure. The bit line structure is disposed over the base structure. The cell contact structure is disposed around the bit line structure, and has a first surface and a second surface facing the bit line structure. A first distance between the first surface of the cell contact structure and the bit line structure is different from a second distance between the second surface of the cell contact structure and the bit line structure.

### TECHNICAL FIELD

The present disclosure relates to a semiconductor structure and a method of manufacturing the same, and more particularly, to a semiconductor structure including bit line structure, and a method of manufacturing the same.

### DISCUSSION OF THE BACKGROUND

Semiconductor structures are used in a variety of electronic applications, and the dimensions of semiconductor structures are continuously being scaled down to meet the current application requirements. However, a variety of issues arise during the scaling-down process and impact the final electrical characteristics, quality, cost and yield. Typical memory devices (such as dynamic random access memory (DRAM) devices) include signal lines, such as word lines and bit lines crossing the word lines. As DRAM devices are scaled down and the dimensions and/or pitches of the signal lines are getting smaller, the parasitic capacitance will be a critical concern.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor structure. The semiconductor structure includes a base structure, a bit line structure and a cell contact structure. The bit line structure is disposed over the base structure. The cell contact structure is disposed around the bit line structure, and has a first surface and a second surface facing the bit line structure. A first distance between the first surface of the cell contact structure and the bit line structure is different from a second distance between the second surface of the cell contact structure and the bit line structure.

Another aspect of the present disclosure provides a semiconductor structure. The semiconductor structure includes a base structure, a bit line structure and a cell contact structure. The bit line structure is disposed over the base structure. The cell contact structure is disposed around the bit line structure, and defines a groove facing the bit line structure. The groove is configured to reduce a width of a surface of the cell contact structure most adjacent to the bit line structure.

Another aspect of the present disclosure provides a method of manufacturing a semiconductor structure. The method includes: providing a base structure, wherein the base structure includes a base portion and at least one active area in the base portion; forming at least one bit line structure over the at least one active area of the base structure; and forming at least one cell contact structure around the at least one bit line structure, wherein the at least one cell contact structure defines a groove facing the at least one bit line structure.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 illustrates, in a flowchart diagram form, a method of manufacturing a semiconductor structure in accordance with one embodiment of the present disclosure.

FIG. 2 illustrates a cross-sectional view of one or more stages of an example of a method of manufacturing a semiconductor structure in accordance with one embodiment of the present disclosure.

FIG. 3 illustrates a cross-sectional view of one or more stages of an example of a method of manufacturing a semiconductor structure in accordance with one embodiment of the present disclosure.

FIG. 4 illustrates a cross-sectional view of one or more stages of an example of a method of manufacturing a semiconductor structure in accordance with one embodiment of the present disclosure.

FIG. 5 illustrates a cross-sectional view of one or more stages of an example of a method of manufacturing a semiconductor structure in accordance with one embodiment of the present disclosure.

FIG. 6 illustrates a cross-sectional view of one or more stages of an example of a method of manufacturing a semiconductor structure in accordance with one embodiment of the present disclosure.

FIG. 7 illustrates a cross-sectional view of one or more stages of an example of a method of manufacturing a semiconductor structure in accordance with one embodiment of the present disclosure.

FIG. 8 illustrates a cross-sectional view of one or more stages of an example of a method of manufacturing a semiconductor structure in accordance with one embodiment of the present disclosure.

FIG. 9 illustrates a cross-sectional view of one or more stages of an example of a method of manufacturing a semiconductor structure in accordance with one embodiment of the present disclosure.

FIG. 10A illustrates a cross-sectional view of one or more stages of an example of a method of manufacturing a semiconductor structure in accordance with one embodiment of the present disclosure.

FIG. 10B illustrates a substantially perspective view of FIG. 10A.

FIG. 11 illustrates a perspective view of one or more stages of an example of a method of manufacturing a semiconductor structure in accordance with one embodiment of the present disclosure.

FIG. 12 illustrates a perspective view of one or more stages of an example of a method of manufacturing a semiconductor structure in accordance with one embodiment of the present disclosure.

FIG. 13 illustrates a perspective view of one or more stages of an example of a method of manufacturing a semiconductor structure in accordance with one embodiment of the present disclosure.

FIG. 14 illustrates a perspective view of one or more stages of an example of a method of manufacturing a semiconductor structure in accordance with one embodiment of the present disclosure.

FIG. 15 illustrates a perspective view of one or more stages of an example of a method of manufacturing a semiconductor structure in accordance with one embodiment of the present disclosure.

FIG. 16 illustrates a perspective view of one or more stages of an example of a method of manufacturing a semiconductor structure in accordance with one embodiment of the present disclosure.

FIG. 17 illustrates a perspective view of one or more stages of an example of a method of manufacturing a semiconductor structure in accordance with one embodiment of the present disclosure.

FIG. 18 illustrates a perspective view of one or more stages of an example of a method of manufacturing a semiconductor structure in accordance with one embodiment of the present disclosure.

FIG. 19 illustrates a perspective view of one or more stages of an example of a method of manufacturing a semiconductor structure in accordance with one embodiment of the present disclosure.

FIG. 20A illustrates a perspective view of one or more stages of an example of a method of manufacturing a semiconductor structure in accordance with one embodiment of the present disclosure.

FIG. 20B illustrates a substantially top view of FIG. 20A.

FIG. 21A illustrates a perspective view of one or more stages of an example of a method of manufacturing a semiconductor structure in accordance with one embodiment of the present disclosure.

FIG. 21B illustrates a substantially top view of FIG. 21A.

FIG. 22A illustrates a perspective view of one or more stages of an example of a method of manufacturing a semiconductor structure in accordance with one embodiment of the present disclosure.

FIG. 22B illustrates a substantially top view of FIG. 22A.

FIG. 23 illustrates a perspective view of one or more stages of an example of a method of manufacturing a semiconductor structure in accordance with one embodiment of the present disclosure.

FIG. 24A illustrates a perspective view of one or more stages of an example of a method of manufacturing a semiconductor structure in accordance with one embodiment of the present disclosure.

FIG. 24B illustrates a substantially top view of FIG. 24A.

FIG. 25A illustrates a perspective view of one or more stages of an example of a method of manufacturing a semiconductor structure in accordance with one embodiment of the present disclosure.

FIG. 25B illustrates a substantially top view of FIG. 25A.

FIG. 26A illustrates a perspective view of one or more stages of an example of a method of manufacturing a semiconductor structure in accordance with one embodiment of the present disclosure.

FIG. 26B illustrates a substantially top view of FIG. 26A.

FIG. 27A illustrates a perspective view of one or more stages of an example of a method of manufacturing a semiconductor structure in accordance with one embodiment of the present disclosure.

FIG. 27B illustrates a substantially top view of FIG. 27A.

FIG. 28A illustrates a perspective view of one or more stages of an example of a method of manufacturing a semiconductor structure in accordance with one embodiment of the present disclosure.

FIG. 28B illustrates a substantially top view of FIG. 28A.

FIG. 29A illustrates a perspective view of one or more stages of an example of a method of manufacturing a semiconductor structure in accordance with one embodiment of the present disclosure.

FIG. 29B illustrates a substantially top view of FIG. 29A.

FIG. 30A illustrates a perspective view of one or more stages of an example of a method of manufacturing a semiconductor structure in accordance with one embodiment of the present disclosure.

FIG. 30B illustrates a substantially top view of FIG. 30A.

FIG. 30C illustrates a top view of at least one first conductive portion of a cell contact structure and a spacer of FIG. 30A.

FIG. 31A illustrates a perspective view of one or more stages of an example of a method of manufacturing a semiconductor structure in accordance with one embodiment of the present disclosure.

FIG. 31B illustrates a substantially top view of FIG. 31A.

FIG. 32A illustrates a perspective view of one or more stages of an example of a method of manufacturing a semiconductor structure in accordance with one embodiment of the present disclosure.

FIG. 32B illustrates a substantially top view of FIG. 32A.

FIG. 33A illustrates a perspective view of one or more stages of an example of a method of manufacturing a semiconductor structure in accordance with one embodiment of the present disclosure.

FIG. 33B illustrates a substantially top view of FIG. 33A.

FIG. 34A illustrates a perspective view of one or more stages of an example of a method of manufacturing a semiconductor structure in accordance with one embodiment of the present disclosure.

FIG. 34B illustrates an enlarged view of an area “A” of FIG. 34A.

FIG. 35A illustrates a perspective view of one or more stages of an example of a method of manufacturing a semiconductor structure in accordance with one embodiment of the present disclosure.

FIG. 35B illustrates a partially enlarged view of FIG. 35A.

FIG. 36 illustrates a cross-sectional view of a semiconductor structure in accordance with some embodiments of the present disclosure.

FIG. 37 illustrates a cross-sectional view taken along line II-II of FIG. 36.

FIG. 38 illustrates an enlarged view of an area “B” of FIG. 37.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

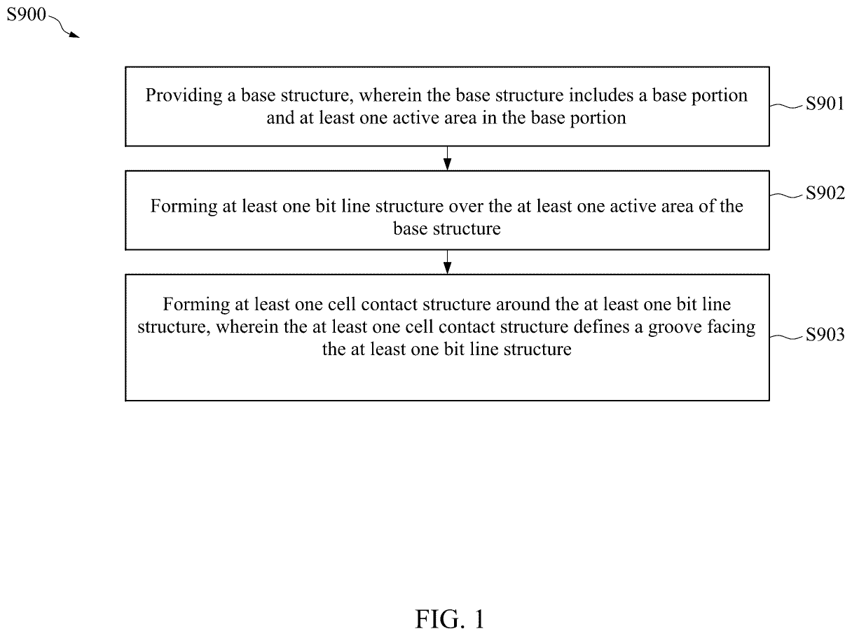

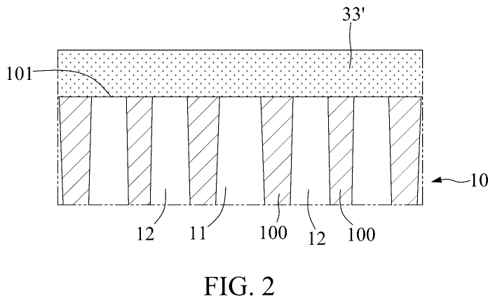

FIG. 1 illustrates, in a flowchart diagram form, a method 900 for manufacturing a semiconductor structure 1 in accordance with one embodiment of the present disclosure. FIGS. 2 to 35B illustrate stages of a method for manufacturing a semiconductor structure 1 in accordance with one embodiment of the present disclosure. At least some of these figures have been simplified for a better understanding of the aspects of the present disclosure.

Referring to FIG. 2, at step S901, a base structure 10 is provided. The base structure 10 may be a substrate, and may include a dielectric material, such as an oxide material or a nitride material. Alternatively, the base structure 10 may be a substrate, and may include, for example, silicon (Si), germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials. In some embodiments, the base structure 10 may include a base portion 100 and at least one active area (e.g., a first active area 11 and a second active area 12) disposed in or embedded in the base portion 100.

The base portion 100 may include dielectric oxide material. Each of the active areas (e.g., the first active area 11 and the second active area 12) may include silicon (Si) material. For example, the first active area 11 may be a drain electrode, and the second active area 12 be a source electrode. In some embodiments, the base structure 10 may have a first surface 101 (e.g., a top surface). The active areas (e.g., the first active area 11 and the second active area 12) may be exposed from the first surface 101 (e.g., the top surface) of the base structure 10.

Then, an insulation layer 33′ may be formed or disposed on the first surface 101 (e.g., the top surface) of the base structure 10. An example of a material of the insulation layer 33′ may include nitride material.

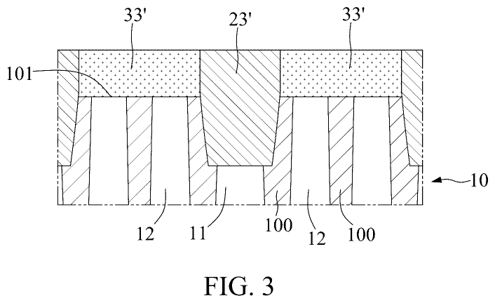

Referring to FIG. 3, at least one conductive material 23′ may be formed to extend through the insulation layer 33′, and may be embedded in the base structure 10. The conductive material 23′ may be formed in a recess portion of the base structure 10 to contact the first active area 11. An example of a material of the conductive material 23′ may include polysilicon.

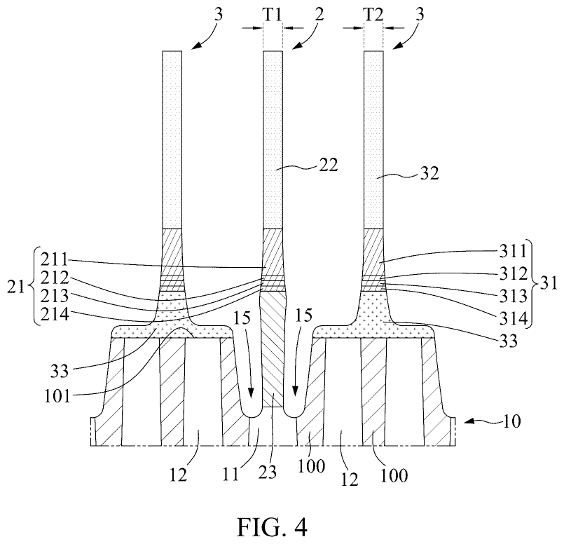

Referring to FIG. 4, at step S902, at least one bit line structure (e.g., a first bit line structure 2 and a second bit line structure 3) is formed over the at least one active area (e.g., the first active area 11 and the second active area 12) of the base structure 10. For example, the first bit line structure 2 may be formed on the conductive material 23′. The second bit line structure 3 may be formed on the insulation layer 33′.

Then, a portion of the insulation layer 33′ may be removed so as to form a plurality of insulators 33 under the second bit line structure 3. In addition, a plurality of recess portions 15 may be formed at two sides of the conductive material 23′ so as to form a plurality of conductors 23 under the first bit line structure 2. The recess portions 15 may be recessed from the first surface 101 (e.g., the top surface) of the base structure 10.

The at least one bit line structure may include a plurality of bit line structures, e.g., the first bit line structure 2 and the second bit line structure 3, and may be disposed on the first surface 101 (e.g., a top surface) of the base structure 10. The first bit line structure 2 may include a main portion 21 and a cap portion 22 disposed on the main portion 21. The main portion 21 may include a tungsten (W) layer 211, a tungsten silicide (WSi₂) layer 212, a tungsten nitride (WN) layer 213 and a titanium (Ti) layer 214. The cap portion 22 may include silicon nitride (SiN). The first bit line structure 2 may have a thickness T1.

The main portion 21 of the first bit line structure 2 may be electrically connected to the first active area 11 through the conductor 23. The conductor 23 may be an electrical contact and may be disposed between the main portion 21 of the first bit line structure 2 and the first active area 11. The first active area 11 may be disposed right under the first bit line structure 2. The first active area 11 may completely vertically overlap the first bit line structure 2. The entire first bit line structure 2 may be disposed within a vertical projection of the first active area 11.

The second bit line structure 3 may include a main portion 31 and a cap portion 32 disposed on the main portion 31. The structure of the second bit line structure 3 may be the same as or similar to the structure of the first bit line structure 2. The main portion 31 may include a tungsten (W) layer 311, a tungsten silicide (WSi₂) layer 312, a tungsten nitride (WN) layer 313 and a titanium (Ti) layer 314. The cap portion 32 may include silicon nitride (SiN). The main portion 31 of the second bit line structure 3 may be electrically insulated from the base structure 10 through the insulator 33. The insulator 33 may be an electrical insulator and may be disposed between the main portion 31 of the second bit line structure 3 and the base structure 10. The second bit line structure 3 may have a thickness T2 that may be equal to the thickness T2 of the first bit line structure 2.

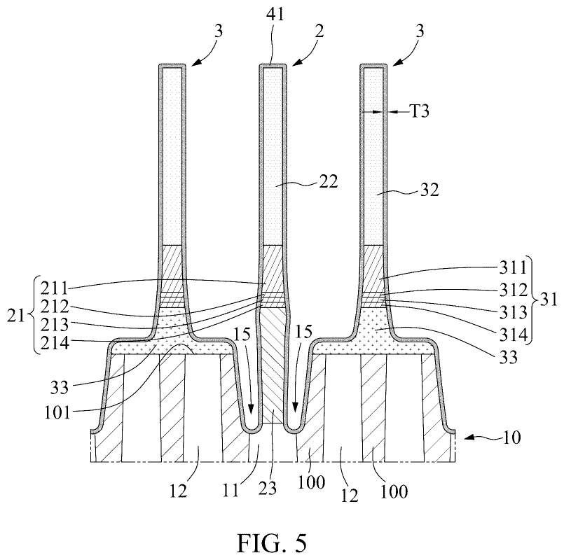

Referring to FIG. 5, a first layer 41 may be formed or disposed to cover and contact the at least one bit line structure (e.g., the first bit line structure 2 and the second bit line structure 3), the insulators 33 and the conductors 23. The first layer 41 may include silicon nitride (SiN) or silicon oxycarbide (SiCO), and may be formed by deposition. The first layer 41 may have a thickness T3.

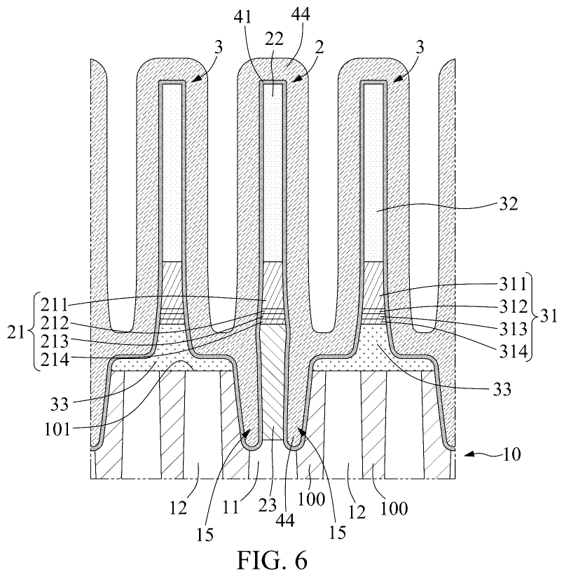

Referring to FIG. 6, a refilling material 44 may be formed or disposed to cover and contact the first layer 41. The refilling material 44 may include nitride material such as silicon nitride (SiN), and may be formed by deposition. The refilling material 44 may fill the recess portions 15.

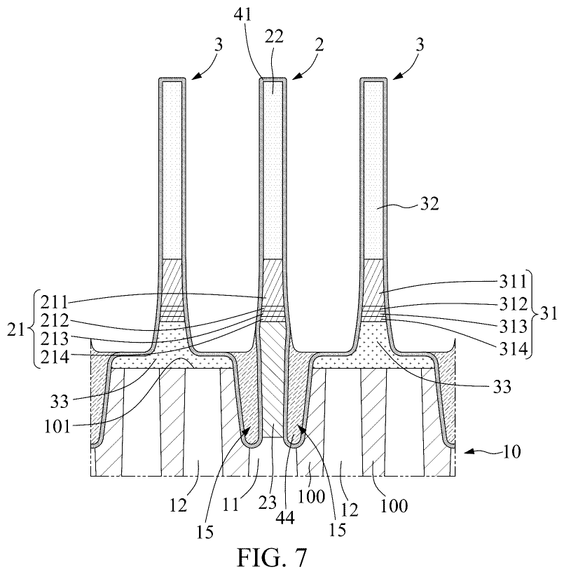

Referring to FIG. 7, portions of the refilling material 44 that are disposed outside the recess portions 15 may be removed.

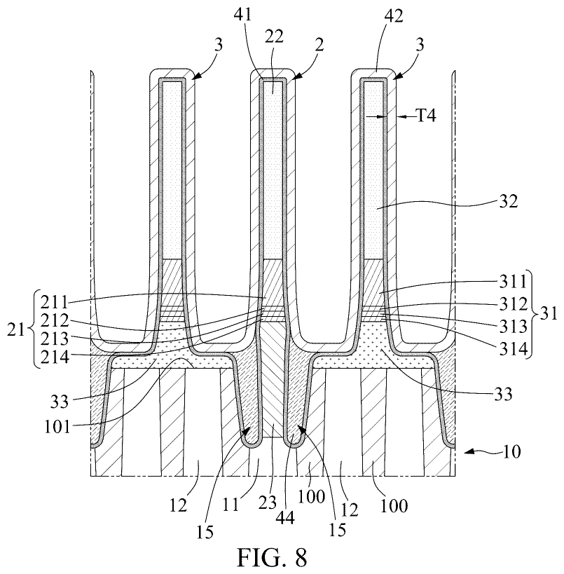

Referring to FIG. 8, a second layer 42 may be formed or disposed to cover and contact the first layer 41 and the refilling material 44. The second layer 42 may include oxide material such as silicon oxide (SiO₂), and may be formed by deposition. The second layer 42 may have a thickness T4. In some embodiments, the thickness T4 of the second layer 42 is greater than the thickness T3 of the first layer 41.

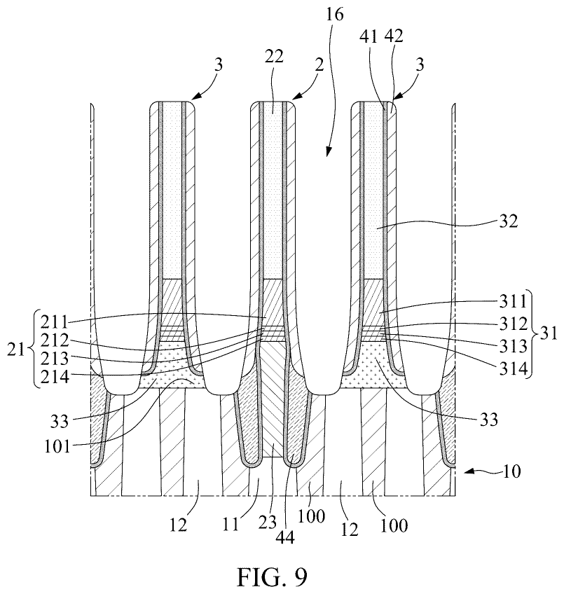

Referring to FIG. 9, the portions of the first layer 41 and the second layer 42 that are disposed on the top surfaces of the bit line structures (e.g., the first bit line structure 2 and the second bit line structure 3) and on the bottom of the trenches 16 (or recess portions) formed between the bit line structures (e.g., the first bit line structure 2 and the second bit line structure 3) may be removed by dry etching.

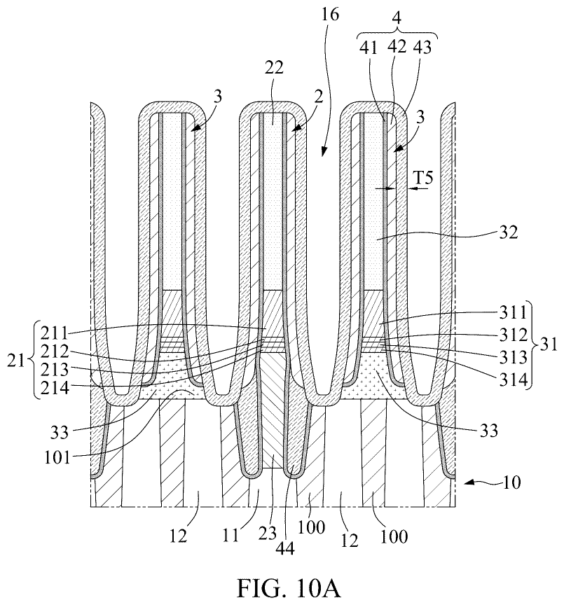

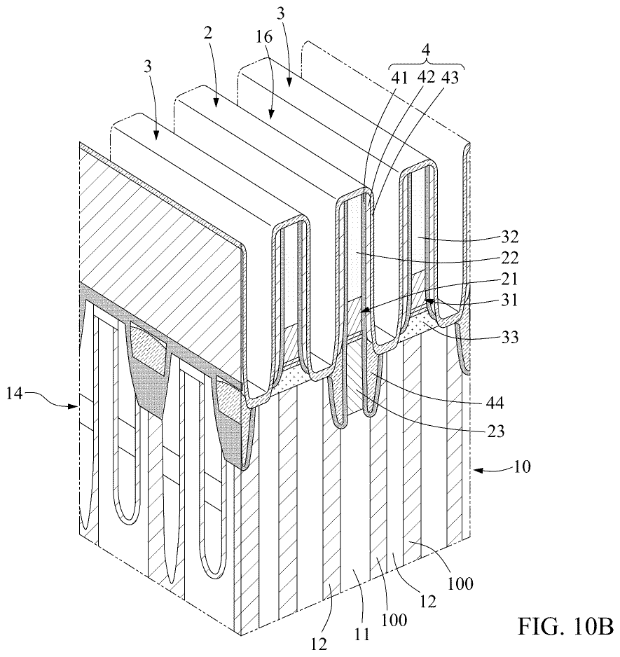

Referring to FIGS. 10A and 10B, wherein FIG. 10B is a substantially perspective view of FIG. 10A, a third layer 43 may be formed or disposed to cover and contact the second layer 42, the top surfaces of the bit line structures (e.g., the first bit line structure 2 and the second bit line structure 3) and the bottom of the trenches 16 (or recess portions) formed between the bit line structures (e.g., the first bit line structure 2 and the second bit line structure 3). The third layer 43 may include nitride material such as silicon nitride (SiN), and may be formed by deposition. In some embodiments, a thickness T5 of the third layer 43 may be less than, equal to or greater than the thickness T4 of the second layer 42. As shown in FIG. 10B, a plurality of word line structures 14 may be embedded in the base structure 10. The extending direction of the word line structure 14 may be substantially perpendicular to the extending direction of the line structure (e.g., the first bit line structure 2 and the second bit line structure 3).

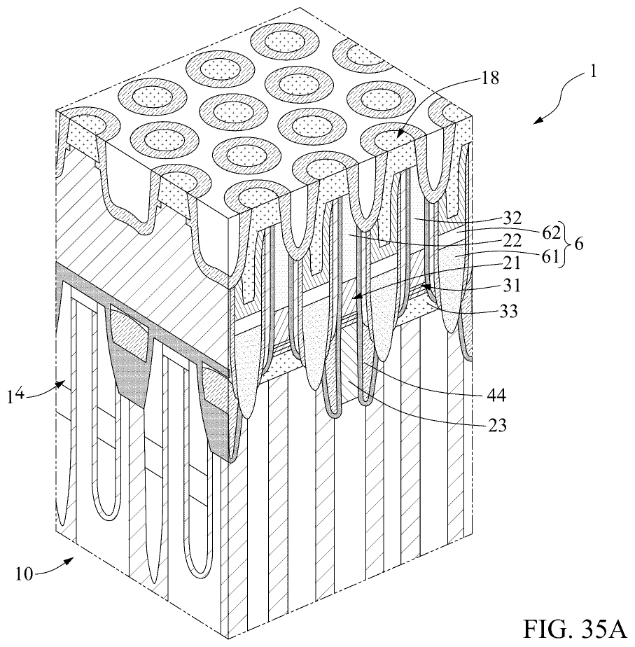

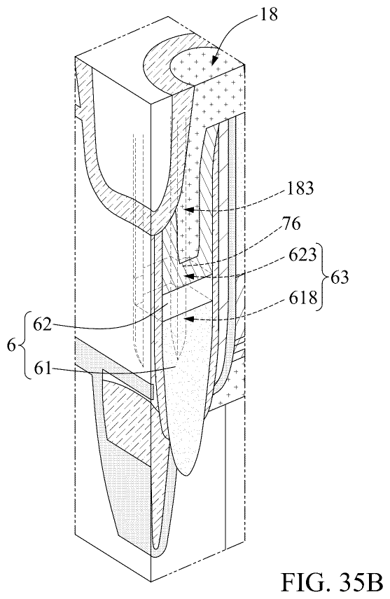

In some embodiments, the first layer 41, the second layer 42 and the third layer 43 may collectively formed a spacer 4 around the bit line structure 2, 3. As shown in FIG. 35A, the spacer 4 may be disposed between the bit line structure 2, 3 and the cell contact structure 6. The spacer 4 may be disposed around the cell contact structure 6.

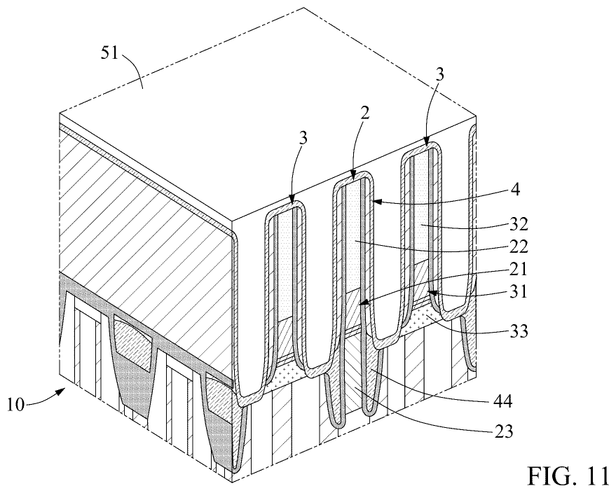

Referring to FIGS. 11 to 35B, at step S903, at least one cell contact structure 6 may be formed or disposed around the bit line structure 2, 3. The cell contact structure 6 may define a groove 63 facing the bit line structure 2, 3.

Referring to FIG. 11, a first insulation material 51 may be formed or disposed to cover and contact the bit line structures (e.g., the first bit line structure 2 and the second bit line structure 3). The first insulation material 51 may further fill the trenches 16 (or recess portions) formed between the bit line structures (e.g., the first bit line structure 2 and the second bit line structure 3). Thus, the entire top surface of the first insulation material 51 may be a flat surface. The first insulation material 51 may include oxide material such as silicon oxide (SiO₂), and may be formed by deposition.

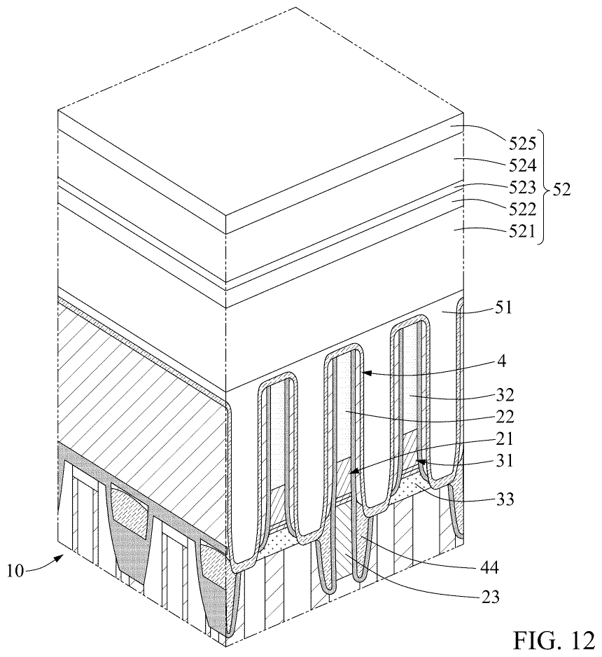

Referring to FIG. 12, a sacrificial structure 52 may be formed or disposed on the first insulation material 51. The sacrificial structure 52 may include a first carbon layer 521, a first anti-reflective coating (ARC) layer 522, a second anti-reflective coating (ARC) layer 523, a second carbon layer 524, and a third anti-reflective coating (ARC) layer 525 stacked on one another.

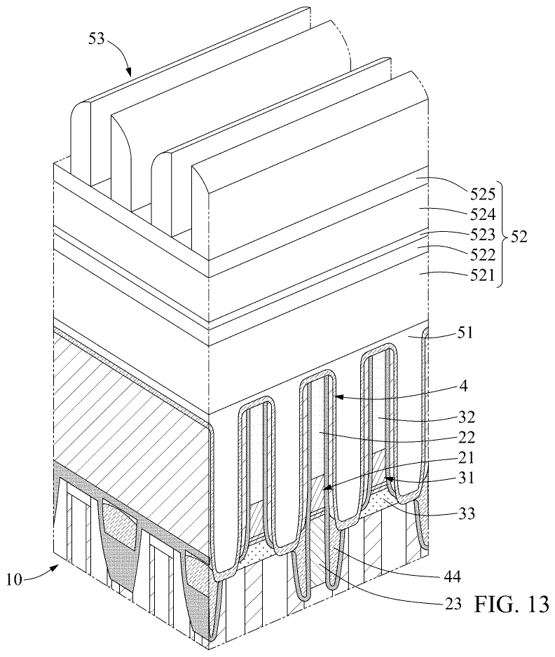

Referring to FIG. 13, a first mask layer 53 may be formed or disposed on the sacrificial structure 52. The first mask layer 53 may be a hard mask.

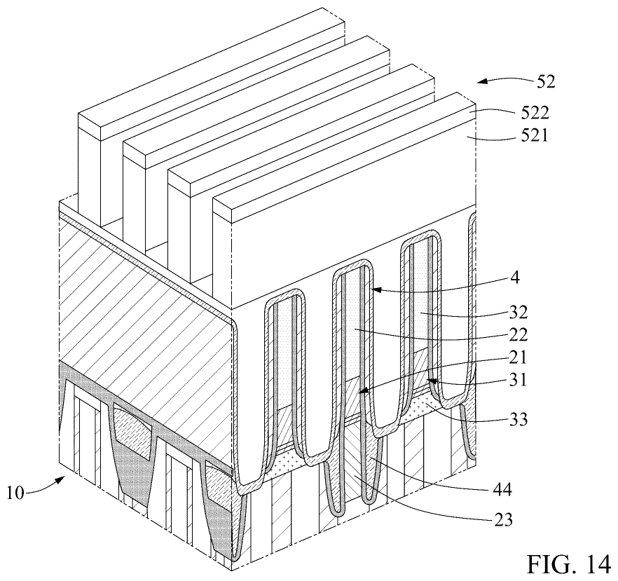

Referring to FIG. 14, the sacrificial structure 52 may be patterned through the first mask layer 53. Then, the first mask layer 53, the second anti-reflective coating (ARC) layer 523, the second carbon layer 524 and the third anti-reflective coating (ARC) layer 525 may be removed. The first carbon layer 521 and the first anti-reflective coating (ARC) layer 522 may remain, and may be patterned to include a plurality of separated rectangular plates by dry etching.

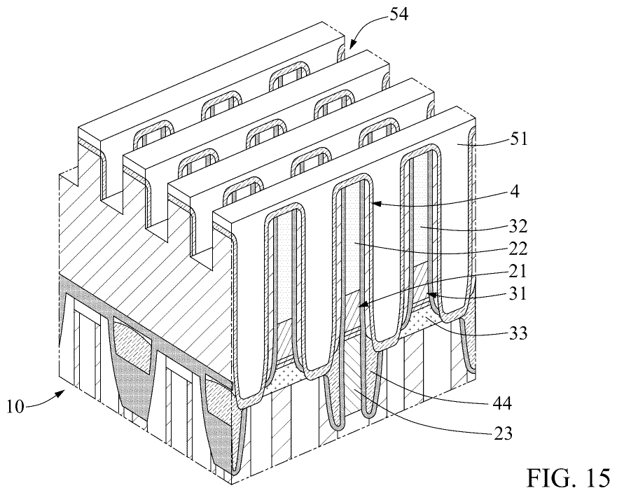

Referring to FIG. 15, a plurality of trenches 54 may be formed in the first insulation material 51 through the patterned sacrificial structure 52 (e.g., the patterned first carbon layer 521 and first anti-reflective coating (ARC) layer 522) by removing a plurality of portions of the first insulation material 51. Then, the patterned sacrificial structure 52 (e.g., the patterned first carbon layer 521 and first anti-reflective coating (ARC) layer 522) may be removed. The trenches 54 may be formed by dry etching. The extending direction of the trenches 54 may be substantially perpendicular to the extending direction of the bit line structures (e.g., the first bit line structure 2 and the second bit line structure 3). The depths of the trenches 54 may be less than the heights of the bit line structures (e.g., the first bit line structure 2 and the second bit line structure 3).

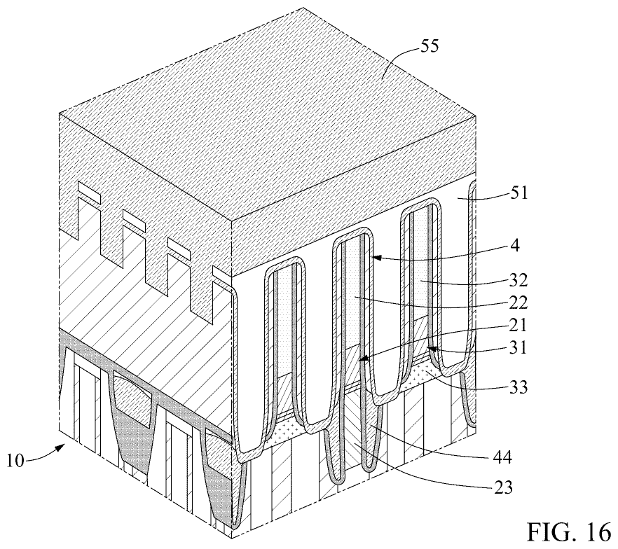

Referring to FIG. 16, a second insulation material 55 may be formed or disposed on the top surface of the first insulation material 51 and may fill the trenches 54. The second insulation material 55 may include nitride material such as silicon nitride (SiN), and may be formed by deposition. The material of the second insulation material 55 may be same as the material of the third layer 43.

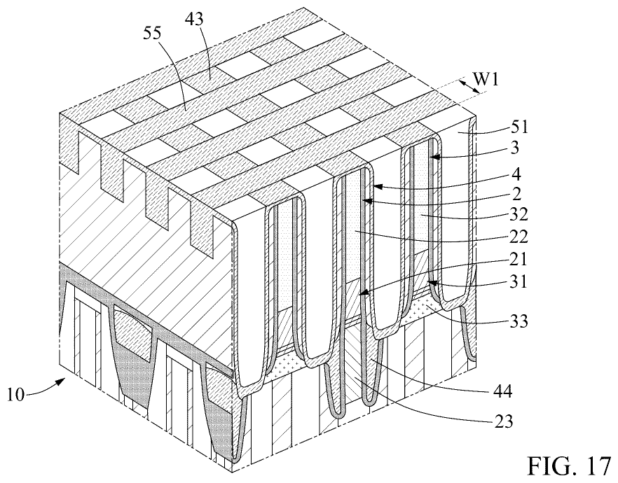

Referring to FIG. 17, the portion of the second insulation material 55 that is disposed above the top surface of the first insulation material 51 may be removed by dry etching. In addition, the portion of the first insulation material 51 that is disposed above the third layer 43 may be further removed by dry etching. Thus, the top surface of the third layer 43 may be exposed. The remaining second insulation material 55 and the exposed third layer 43 may collectively form a grid structure or a net structure from a top view. In some embodiments, there may be no interface between the remaining second insulation material 55 and the exposed third layer 43. However, in another embodiments, there may be an interface between the remaining second insulation material 55 and the exposed third layer 43. In some embodiments, the remaining second insulation material 55 width W1.

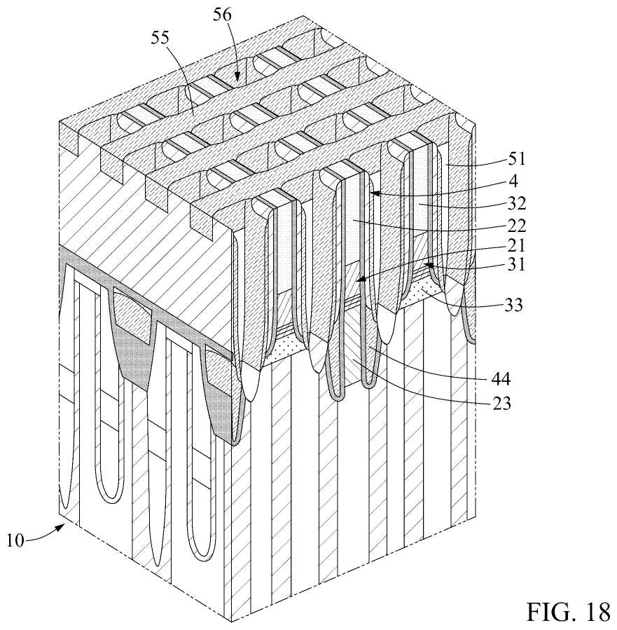

Referring to FIG. 18, a removing process (e.g., a punch etching process) may be conducted to remove the first insulation material 51 enclosed by the remaining second insulation material 55 and the exposed third layer 43, and to remove a portion of the base portion 100 and a portion of the second active area 12, so as to from a plurality of openings 56. Each of the openings 56 may be enclosed by the remaining second insulation material 55 and the exposed third layer 43 from a top view. The openings 56 may extend into the base structure 10. Thus, the bottom end of the opening 56 may below the first surface 101 (e.g., the top surface) of the base structure 10. In some embodiments, the top surface of the cap portion 32 of the second bit line structure 3, the top surface of the cap portion 22 of the first bit line structure 2, the top surface of the first layer 41, the top surface of the second layer 42 and the top surface of the third layer 43 may be exposed.

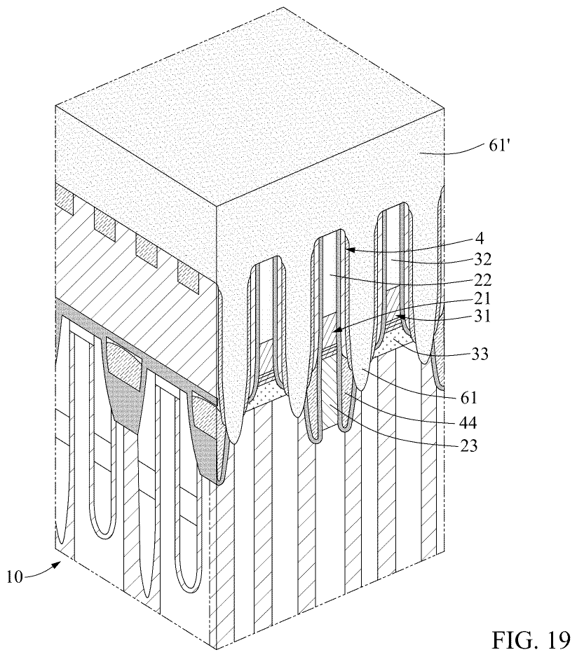

Referring to FIG. 19, a first conductive material 61′ may be formed or disposed on the bit line structures (e.g., the first bit line structure 2 and the second bit line structure 3), the remaining second insulation material 55 and the exposed third layer 43. The first conductive material 61′ may include polysilicon, and may be formed by deposition. The first conductive material 61′ may fill the openings 56.

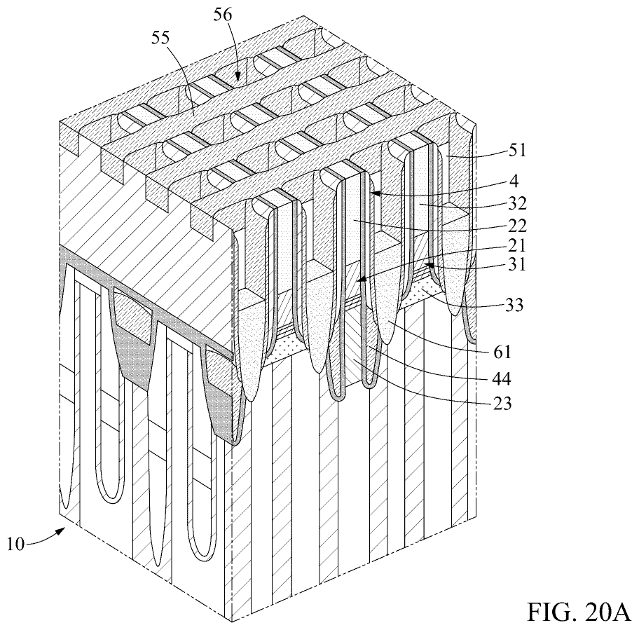

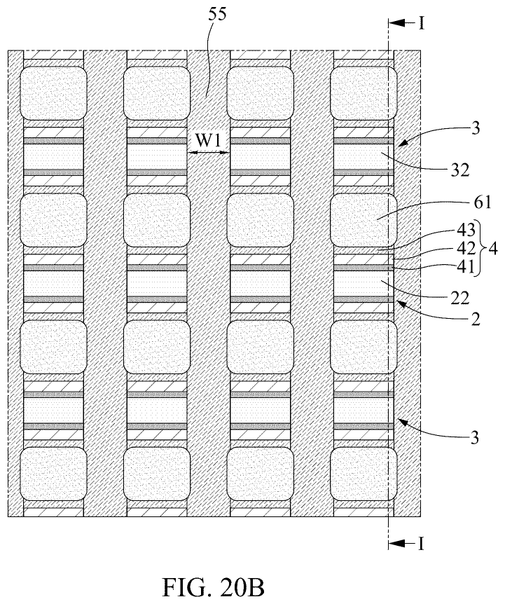

Referring to FIGS. 20A and 20B, wherein FIG. 20B is a substantially top view of FIG. 20A, the right side of FIG. 20A is taken along line I-I of FIG. 20B, portions of the first conductive material 61′ may be removed by etching. The remaining portion of the first conductive material 61′ disposed in an opening 56 may be referred to as a first conductive portion 61 of a cell contact structure 6 (FIG. 35A). The top surface of the first conductive portion 61 may be substantially aligned with or substantially leveled with the top surface of the main portion 21 of the first bit line structure 2 and/or the top surface of the main portion 31 of the second bit line structure 3. The first conductive portion 61 may contact the base portion 100 and the second active area 12.

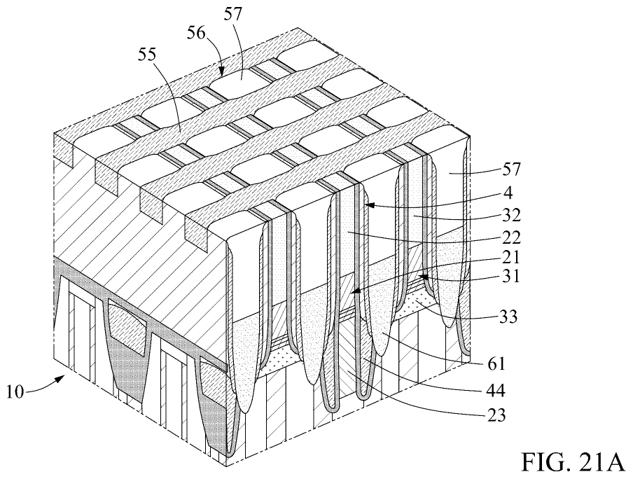

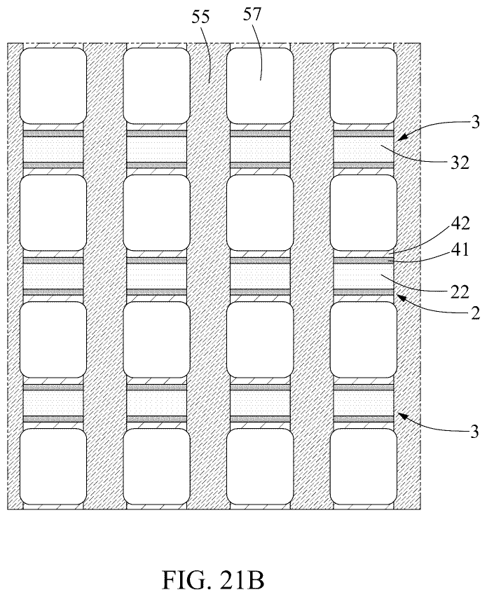

Referring to FIGS. 21A and 21B, wherein FIG. 21B is a substantially top view of FIG. 21A, a first sacrificial material 57 may be formed or disposed in the opening 56 and on the first conductive portion 61. The first sacrificial material 57 may include an anti-reflective coating (ARC) material, and may be formed by deposition. The first sacrificial material 57 may fill the opening 56.

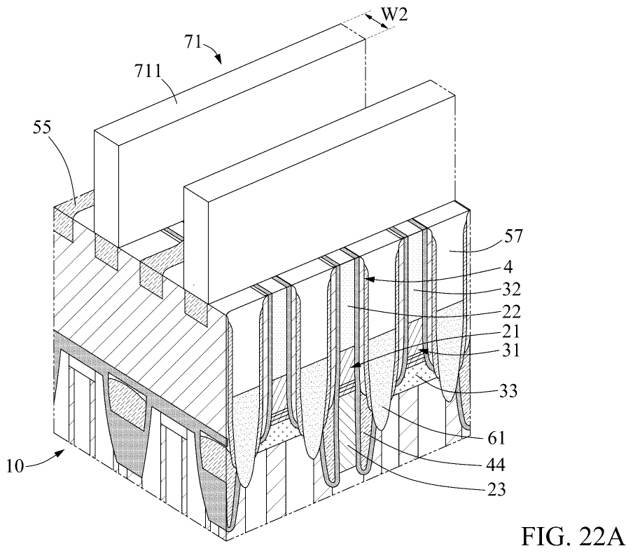

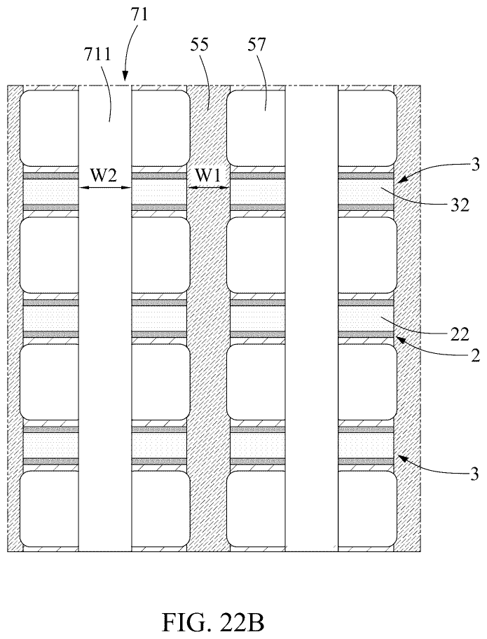

Referring to FIGS. 22A and 22B, wherein FIG. 22B is a substantially top view of FIG. 22A, a first photoresist structure 71 may be formed or disposed on the remaining second insulation material 55. The first photoresist structure 71 may include a plurality of separated rectangular plates 711 (or remaining portions or main portions). The extending direction of the rectangular plate 711 may be the same as the extending direction of the remaining second insulation material 55. A width W2 (or a thickness) of the rectangular plate 711 may be slightly greater than the width W1 of the remaining second insulation material 55. Thus, the rectangular plate 711 may cover and contact a portion of the top surface of the first sacrificial material 57, a portion of the top surface of the cap portion 32 of the second bit line structure 3, a portion of the top surface of the cap portion 22 of the first bit line structure 2, a portion of the top surface of the first layer 41 and a portion of the top surface of the second layer 42.

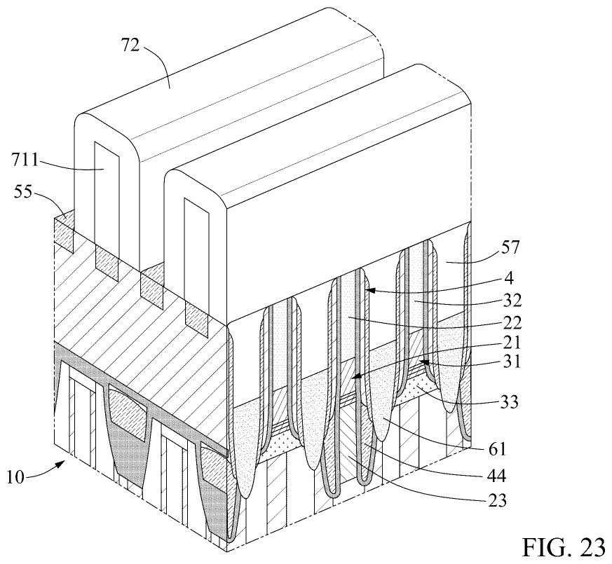

Referring to FIG. 23, an insulation layer 72 (or dielectric layer) may be formed or disposed to cover the rectangular plates 711 and the gap (or space) between the rectangular plates 711.

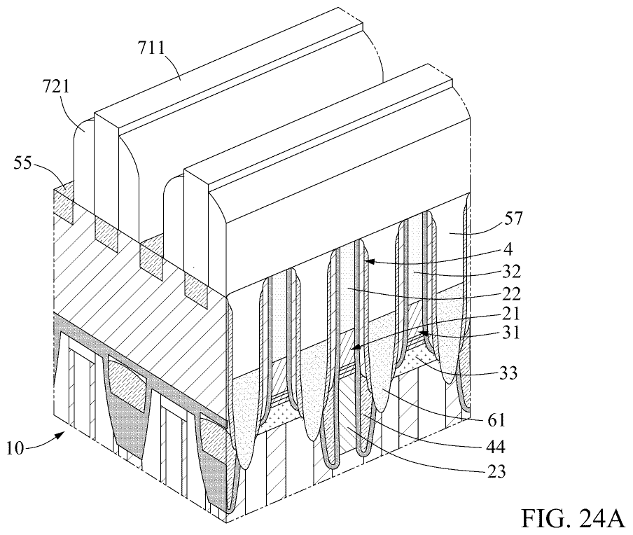

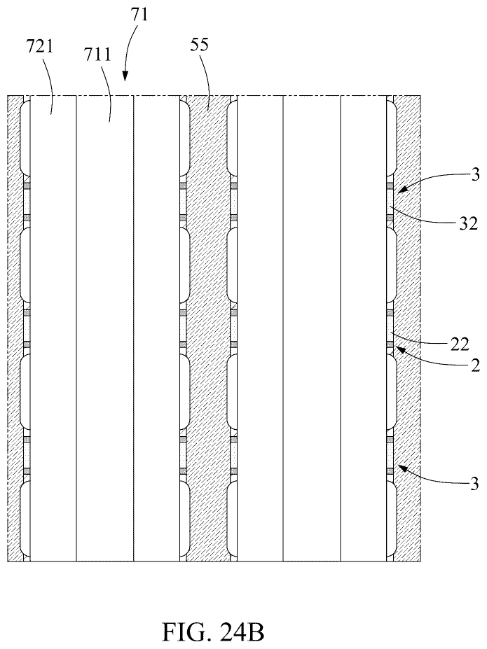

Referring to FIGS. 24A and 24B, wherein FIG. 24B is a substantially top view of FIG. 24A, an etching may be conducted to removing portions of the insulation layer 72 so as to form a plurality of separated spacers 721 on the lateral surfaces of the rectangular plates 711.

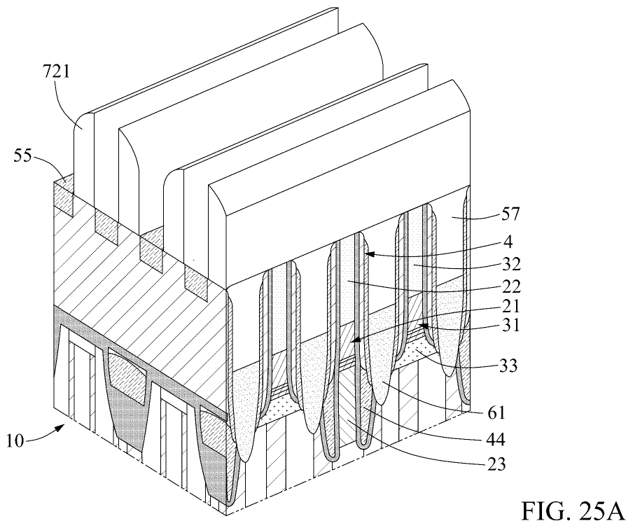

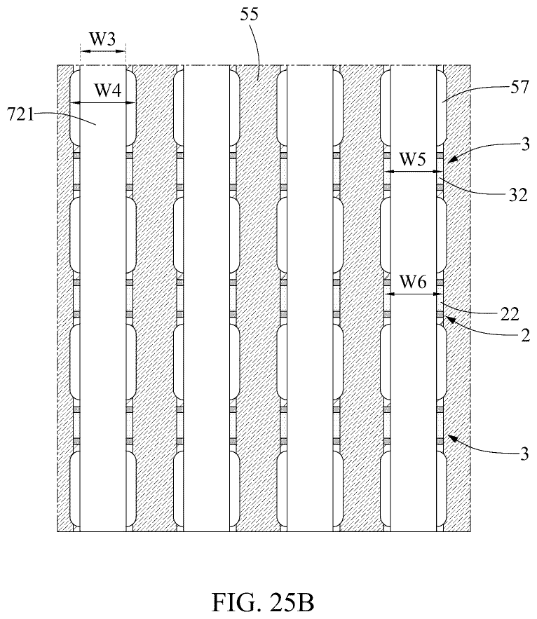

Referring to FIGS. 25A and 25B, wherein FIG. 25B is a substantially top view of FIG. 25A, the rectangular plates 711 may be removed by stripping. The spacers 721 may remain to expose the remaining second insulation material 55. A width W3 (or a thickness) of the spacer 721 may be less than a width W4 of the first sacrificial material 57, a width W5 of the cap portion 32 of the second bit line structure 3 and a width W6 of the cap portion 22 of the first bit line structure 2. Thus, a portion of the top surface of the first sacrificial material 57, a portion of the top surface of the cap portion 32 of the second bit line structure 3, a portion of the top surface of the cap portion 22 of the first bit line structure 2, a portion of the top surface of the first layer 41 and a portion of the top surface of the second layer 42 may be not covered by the spacer 721, and may be exposed by the spacer 721 from the top view. That is, the spacer 721 may not completely cover the first sacrificial material 57, the cap portion 32 of the second bit line structure 3, the cap portion 22 of the first bit line structure 2, the first layer 41 and the second layer 42.

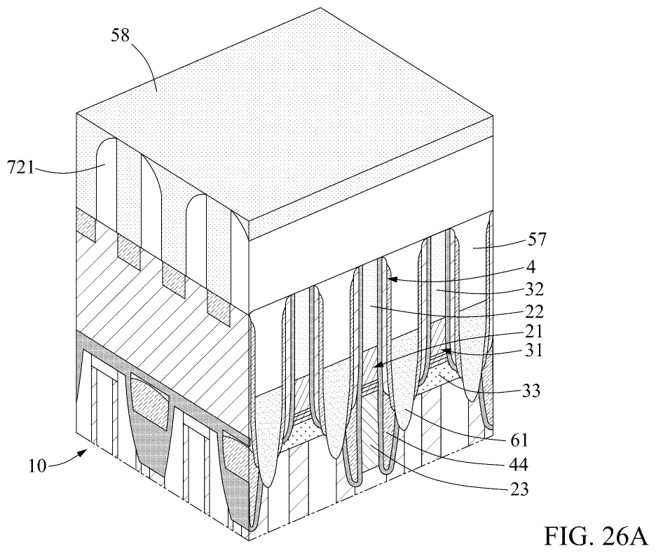

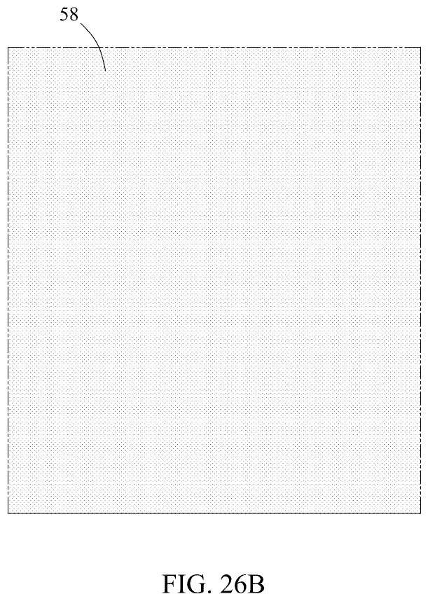

Referring to FIGS. 26A and 26B, wherein FIG. 26B is a substantially top view of FIG. 26A, a second sacrificial material 58 may be formed or disposed on the spacers 721. The second sacrificial material 58 may include an anti-reflective coating (ARC) material, and may be formed by deposition. The second sacrificial material 58 may fill the gap or space between the spacers 721.

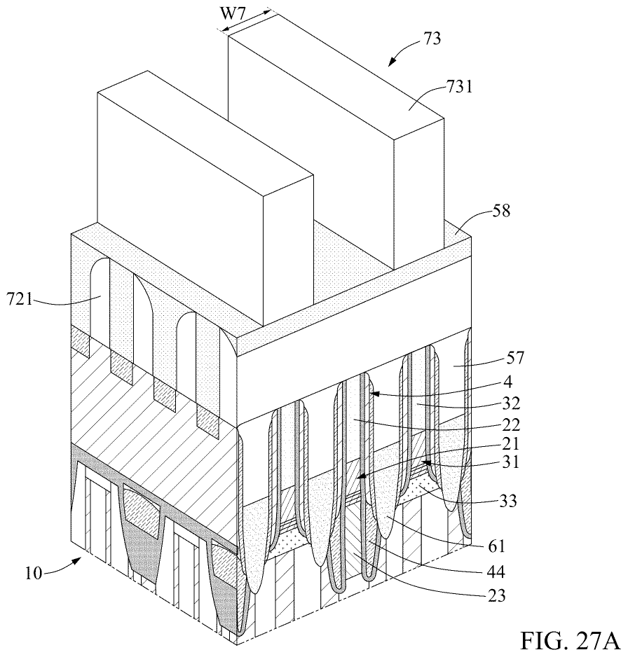

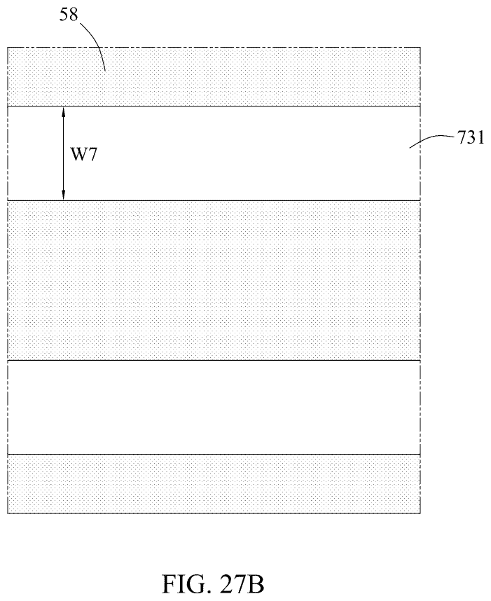

Referring to FIGS. 27A and 27B, wherein FIG. 27B is a substantially top view of FIG. 27A, a second photoresist structure 73 may be formed or disposed on the second sacrificial material 58. The second photoresist structure 73 may include a plurality of separated rectangular plates 731 (or remaining portions or main portions). The extending direction of the rectangular plate 731 may be substantially perpendicular to the extending direction of the spacer 721. A width W7 (or a thickness) of the rectangular plate 731 may be slightly greater than a sum of the thickness T2 of the second bit line structure 3, two times of the thickness T3 of the first layer 41 on the second bit line structure 3, two times of the thickness T4 of the second layer 42 on the first layer 41 and two times of the thickness T5 of the third layer 43 on the second layer 42. Thus, the second bit line structure 3, two first layers 41 on the second bit line structure 3, two second layers 42 on the two first layers 41, and two third layers 43 on the two second layers 42 are entirely disposed within a vertical projection of the rectangular plate 731.

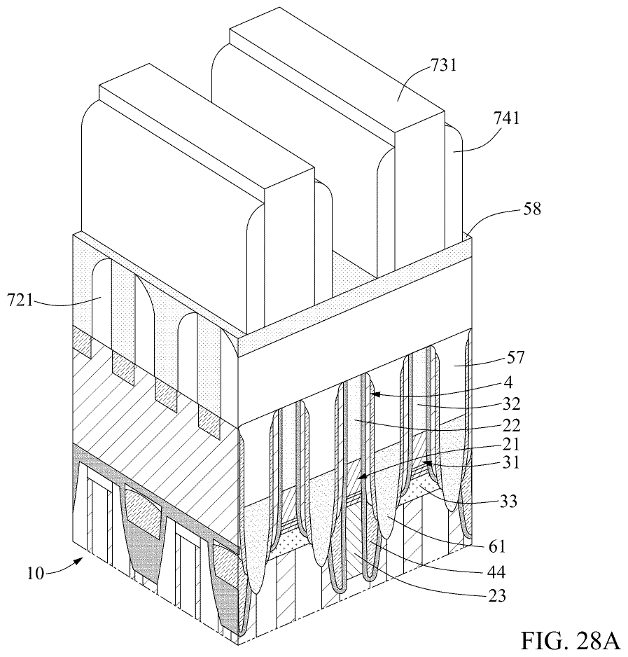

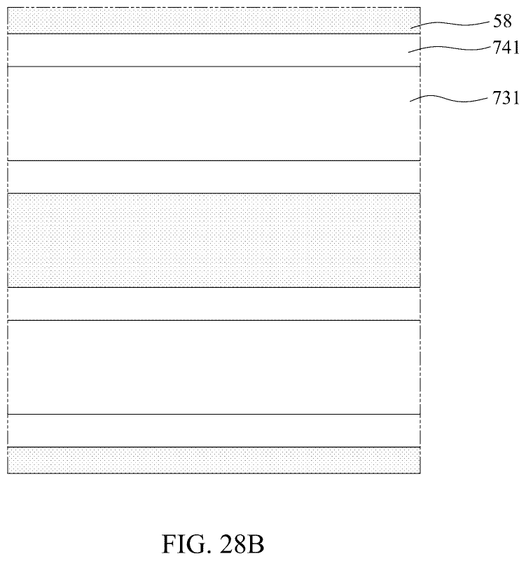

Referring to FIGS. 28A and 28B, wherein FIG. 28B is a substantially top view of FIG. 28A, a plurality of separated spacers 741 may be formed on the lateral surfaces of the rectangular plates 731.

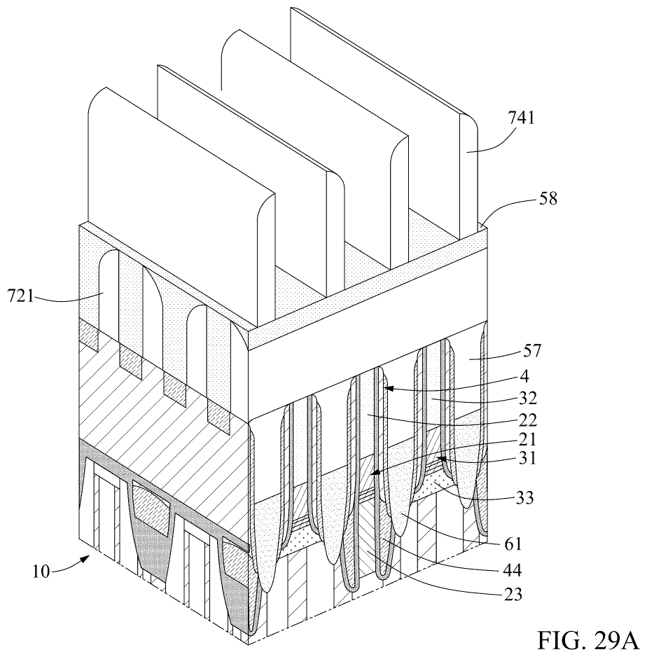

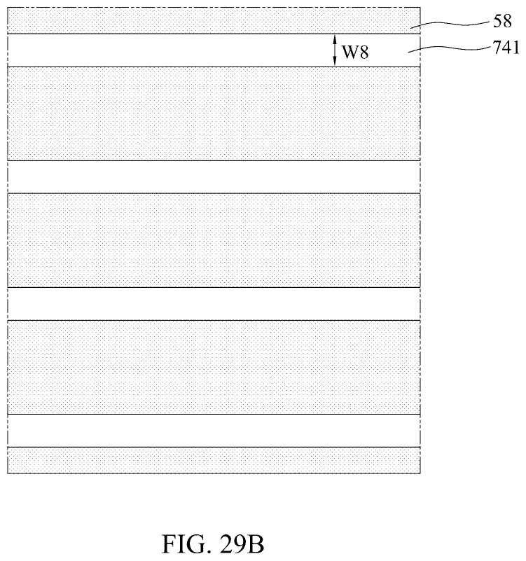

Referring to FIGS. 29A and 29B, wherein FIG. 29B is a substantially top view of FIG. 29A, the rectangular plates 731 may be removed by stripping. The spacers 741 may remain to expose the second sacrificial material 58. A width W8 (or a thickness) of the spacer 741 may be less than the width W4 of the first sacrificial material 57. Thus, a portion of the first sacrificial material 57 may be not covered by the spacer 741. That is, the spacer 741 may not completely cover the first sacrificial material 57.

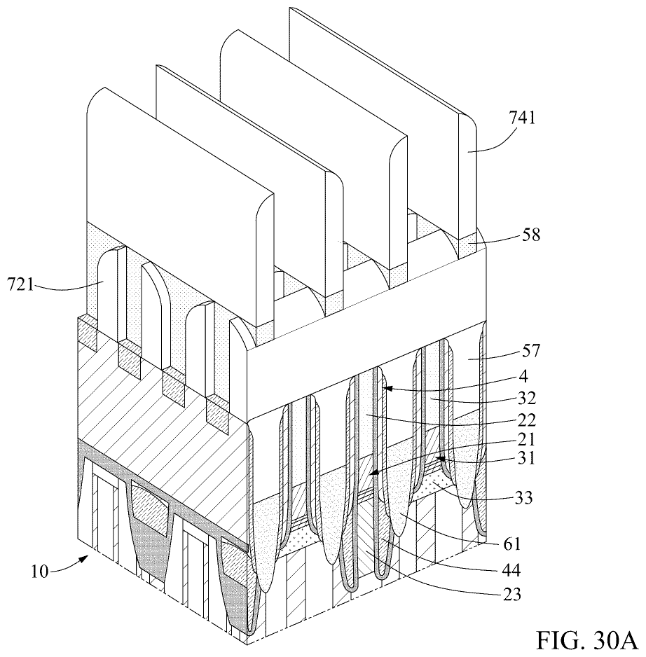

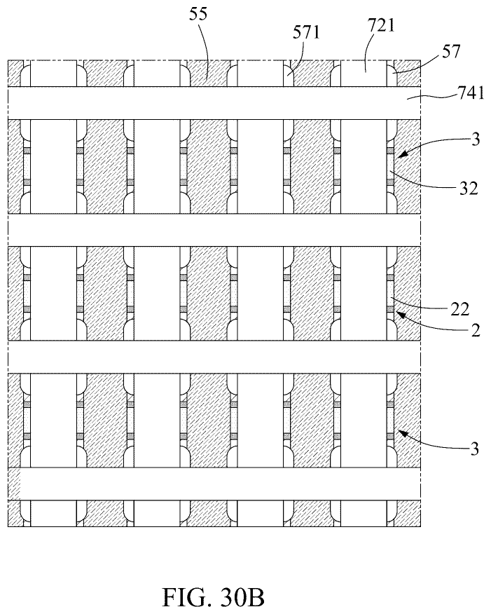

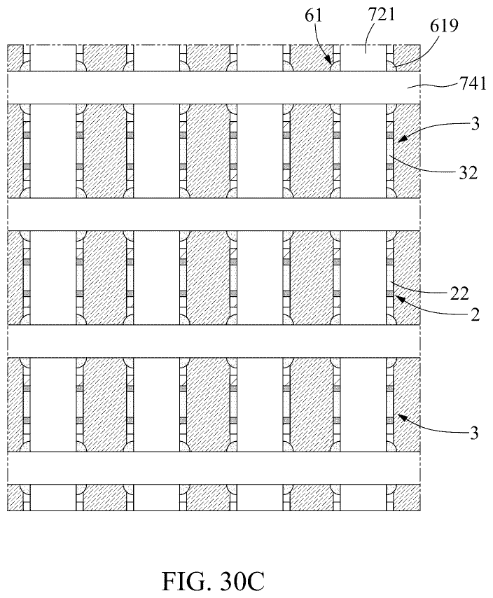

Referring to FIGS. 30A and 30B, wherein FIG. 30B is a substantially top view of FIG. 30A, the portions of the second sacrificial material 58 that are not covered by the spacers 741 may be removed. Meanwhile, the spacers 741 may be disposed over the spacers 721. The spacers 741 may be substantially perpendicular to the spacers 721. The spacers 741 and the spacers 721 may collectively form a grid structure or a net structure from the top view. As shown in FIG. 30B, four corner ends 571 of the first sacrificial material 57 may be not covered by the spacers 741 and the spacers 721 from the top view. That is, in the top view, the four corner ends 571 of the first sacrificial material 57 may be exposed by an intersection of the spacer 741 and the spacer 721.

Referring to FIG. 30C, at least one first conductive portion 61 of a cell contact structure 6 (FIG. 35A), the spacer 741 and the spacer 721 are illustrated. Four corner ends 619 of the first conductive portion 61 may be not covered by the spacers 741 and the spacers 721 from the top view. That is, in the top view, the four corner ends 619 of the first conductive portion 61 may be outside of the intersection of the spacer 741 and the spacer 721.

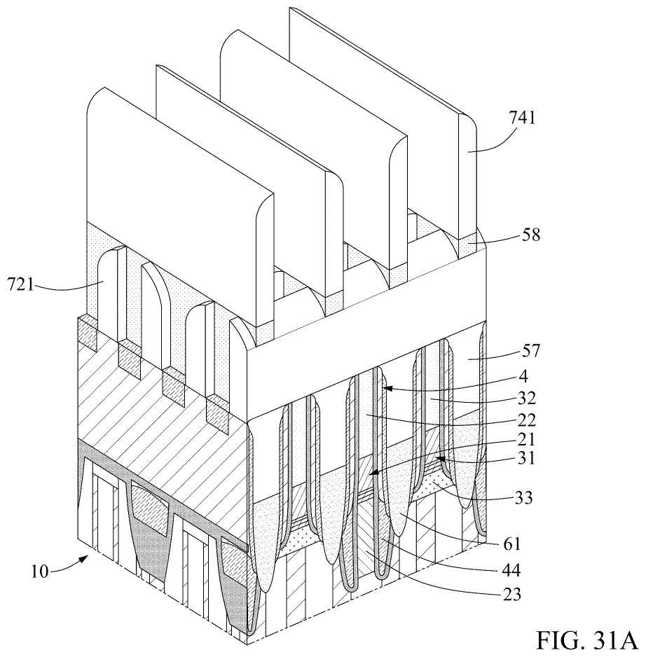

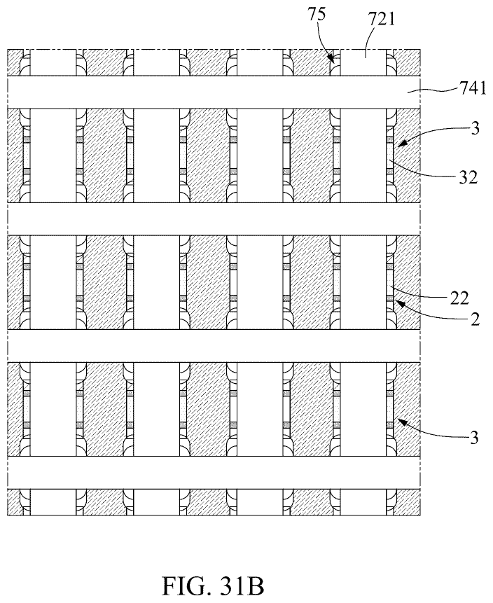

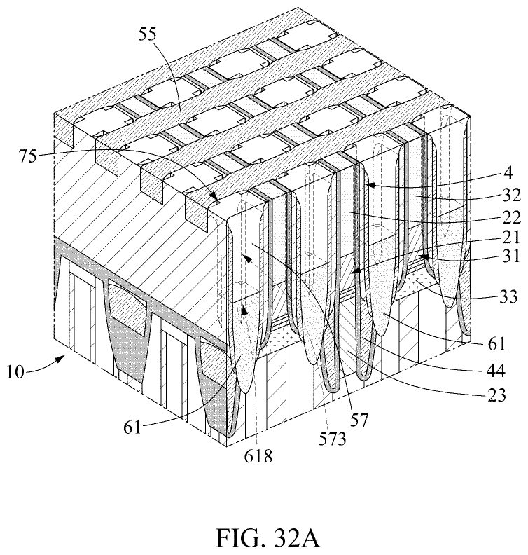

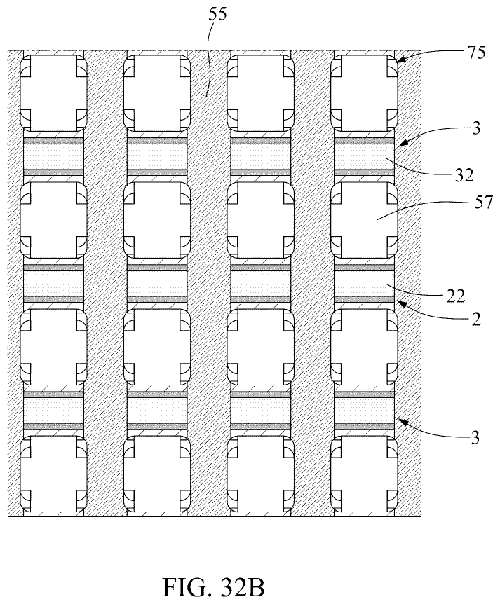

Referring to FIGS. 31A and 31B, wherein FIG. 31B is a substantially top view of FIG. 31A, the corner ends 571 of the first sacrificial material 57 and the corner ends 619 of the first conductive portion 61 may be removed by using the spacers 741 and the spacers 721 as masks in an etching process, so as to form a plurality of holes 75 (including a plurality of temporary groove 573 (FIG. 32C) and a plurality of first groove 618 (FIG. 32C)). That is, the corner end 619 of the first conductive portion 61 (i.e., the first conductive portion 61 of the cell contact structure 6 (FIG. 35A)) may be removed to form the first groove 618. The corner end 571 of the first sacrificial material 57 may be removed to form the temporary groove 573. The first groove 618 and the temporary groove 573 may collectively form the hole 75.

Referring to FIGS. 32A and 32B, wherein FIG. 32B is a substantially top view of FIG. 32A, the spacers 741 and the spacers 721 may be removed. The hole 75 may be an enclosed space defined by the first sacrificial material 57 and the first conductive portion 61 and the remaining second insulation material 55 and the third layer 43. The hole 75 may be located at the corner of the first conductive portion 61 and the corner of the first sacrificial material 57. Thus, the hole 75 may include the first groove 618 and the temporary groove 573.

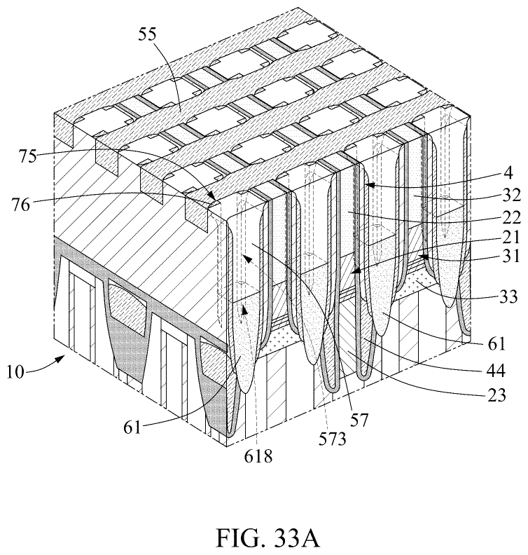

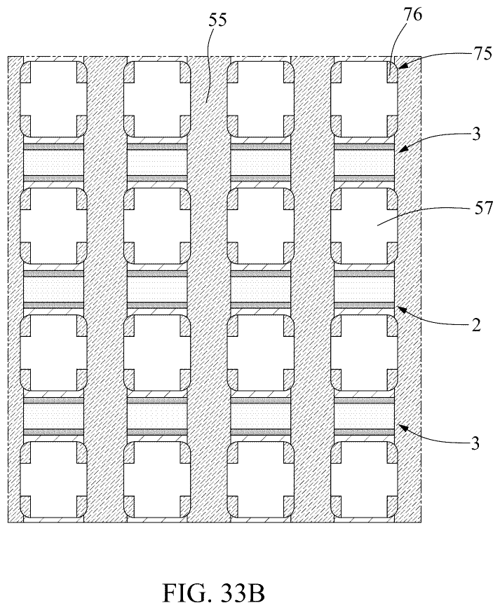

Referring to FIGS. 33A and 33B, wherein FIG. 33B is a substantially top view of FIG. 33A, a filling material 76 may be formed or disposed in and may fill the holes 75. Thus, the filling material 76 may be formed or disposed in the first groove 618 and the temporary groove 573. The filling material 76 may include nitride material such as silicon nitride (SiN), and may be formed by deposition. In some embodiments, there may be no interface between the remaining second insulation material 55, the third layer 43 and the filling material 76. However, in another embodiments, there may be interfaces between the remaining second insulation material 55, the third layer 43 and the filling material 76.

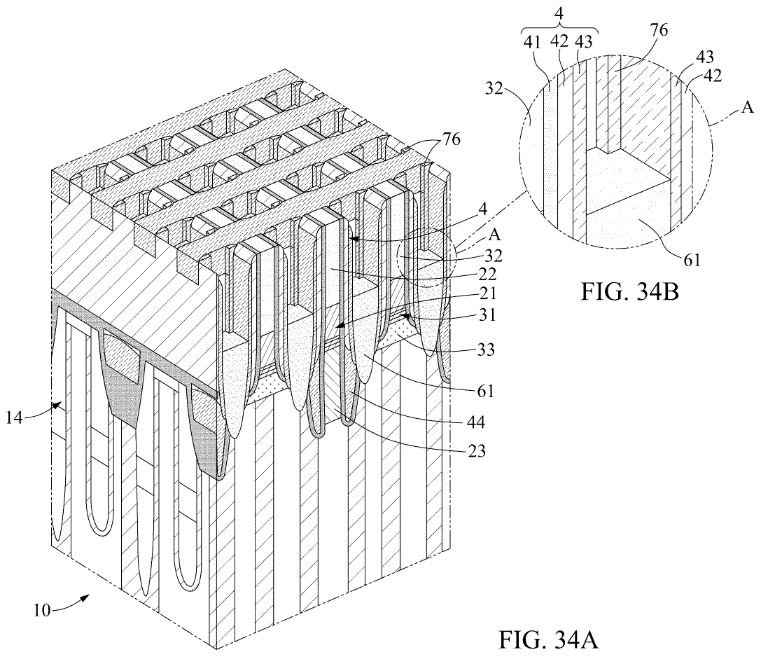

Referring to FIGS. 34A and 34B, wherein FIG. 34B is an enlarged view of an area “A” of FIG. 34A, the first sacrificial material 57 may be removed.

Referring to FIGS. 35A and 35B, wherein FIG. 35B is a partially enlarged view of FIG. 35A, a second conductive portion 62 may be formed in the opening 56 and on the first conductive portion 61 so as to contact the filling material 76. The first conductive portion 61 and the second conductive portion 62 may collectively form a cell contact structure 6. A material of the second conductive portion 62 may include a conductive material such as tungsten (W). The material of the first conductive portion 61 may same as or different from the material of the second conductive portion 62. Then, a plurality of landing pads 18 may be formed on the cell contact structures 6. The landing pad 18 may contact the filling material 76. Meanwhile, a semiconductor structure 1 may be formed or manufactured.

As shown in FIG. 35B, the second conductive portion 62 of the cell contact structure 6 may define a second groove 623. The first groove 618 of the first conductive portion 61 and the second groove 623 the second conductive portion 62 may collectively define a groove 63 of the cell contact structure 6. In addition, the landing pad 18 may define a groove 183 continuous with the groove 63 of the cell contact structure 6.

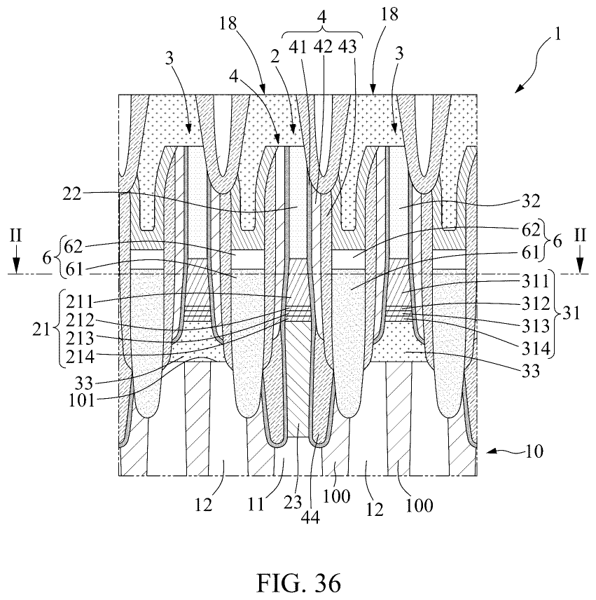

FIG. 36 illustrates a cross-sectional view of a semiconductor structure 1 in accordance with some embodiments of the present disclosure. FIG. 36 may be a right side view of FIG. 35A. In some embodiments, the semiconductor structure 1 may be a semiconductor device that includes a circuit, such as a memory cell. In some embodiments, the memory cell may include a dynamic random access memory cell (DRAM cell).

In addition, the semiconductor structure 1 may be or include a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof.

The semiconductor structure 1 may include a base structure 10, at least one bit line structure (e.g., a first bit line structure 2, and a second bit line structure 3, at least one spacer 4, at least one cell contact structure 6 and at least one landing pad 18.

The base structure 10 may be a substrate, and may include a dielectric material, such as an oxide material or a nitride material. Alternatively, the base structure 10 may be a substrate, and may include, for example, silicon (Si), germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials. In some embodiments, the base structure 10 may include a base portion 100 and at least active area (e.g., a first active area 11 and a second active area 12) disposed in or embedded in the base portion 100. The base portion 100 may include dielectric oxide material. Each of the active areas (e.g., the first active area 11 and the second active area 12) may include silicon (Si) material. For example, the first active area 11 may be a drain electrode. The second active area 12 may be a source electrode.

The base structure 10 may have a first surface 101 (e.g., a top surface). The active areas (e.g., the first active area 11 and the second active area 12) may be exposed from the first surface 101 (e.g., the top surface) of the base structure 10, and may be electrically insulated from each other.

The at least one bit line structure may include a plurality of bit line structures, e.g., the first bit line structure 2 and the second bit line structure 3, and may be disposed over the base structure 10.

The first bit line structure 2 may include a main portion 21 and a cap portion 22 disposed on the main portion 21. The main portion 21 may include a tungsten (W) layer 211, a tungsten silicide (WSi₂) layer 212, a tungsten nitride (WN) layer 213 and a titanium (Ti) layer 214. The cap portion 22 may include silicon nitride (SiN). The first bit line structure 2 may have a thickness T1.

The main portion 21 of the first bit line structure 2 may be electrically connected to the first active area 11 through a conductor 23. The conductor 23 may be an electrical contact and may be disposed between the main portion 21 of the first bit line structure 2 and the first active area 11. An example of a material of the conductor 23 may include polysilicon. The first active area 11 may be disposed right under the first bit line structure 2. A width of the first active area 11 may be greater than a width of the conductor 23. Thus, the first active area 11 may completely vertically overlap the first bit line structure 2. The entire first bit line structure 2 may be disposed within a vertical projection of the first active area 11.

The second bit line structure 3 may include a main portion 31 and a cap portion 32 disposed on the main portion 31. The structure of the second bit line structure 3 may be the same as or similar to the structure of the first bit line structure 2. The main portion 31 may include a tungsten (W) layer 311, a tungsten silicide (WSi2) layer 312, a tungsten nitride (WN) layer 313 and a titanium (Ti) layer 314. The cap portion 32 may include silicon nitride (SiN). The main portion 31 of the second bit line structure 3 may be electrically insulated from the base structure 10 through the insulator 33. The insulator 33 may be an electrical insulator and may be disposed between the main portion 31 of the second bit line structure 3 and the base structure 10. An example of a material of the insulator 33 may include nitride material. The second bit line structure 3 may have a thickness T2 that may be equal to the thickness T1 of the first bit line structure 2.

The spacer 4 may be disposed around or adjacent to the bit line structure (e.g., the first bit line structure 2 and the second bit line structure 3). The spacer 4 may be interposed between the bit line structure (e.g., the first bit line structure 2 and the second bit line structure 3) and the cell contact structure 6.

The spacer 4 may include a first layer 41, a second layer 42 and a third layer 43. The first layer 41 may include silicon nitride (SiN) or silicon oxycarbide (SiCO), and may have a thickness T3. The second layer 42 may include oxide material such as silicon oxide (SiO₂), and may have a thickness T4. The third layer 43 may include nitride material such as silicon nitride (SiN), and may have a thickness T5.

The second layer 42 may be interposed between the first layer 41 and the third layer 43. The first layer 41 may be interposed between the second layer 42 and the first bit line structure 2. The thickness T3 of the first layer 41 may be less than the thickness T4 of the second layer 42. The material of the first layer 41 may be different from the material of the second layer 42. In addition, the third layer 43 may be interposed between the second layer 42 and the cell contact structure 6. The thickness T5 of the third layer 43 may be less than, equal to or greater than the thickness T4 of the second layer 42. The material of the first layer 41 may be same as or different from the material of the third layer 43.

In addition, a plurality of recess portions 15 may be recessed from the first surface 101 (e.g., the top surface) of the base structure 10. The recess portions 15 may be disposed around the conductor 23. The first layer 41 may be further disposed on the sidewall of the recess portions 15. A refilling material 44 may be disposed on the first layer 41 to fill the recess portions 15. Thus, the refilling material 44 may be formed or disposed under the second layer 42 and the third layer 43. The refilling material 44 may include nitride material such as silicon nitride (SiN). The material of the refilling material 44 may be same as or different from the material of the third layer 43.

The cell contact structure 6 may be disposed around the bit line structure (e.g., the first bit line structure 2 and the second bit line structure 3). The cell contact structure 6 may be electrically connected to the second active area 12. In some embodiments, the cell contact structure 6 may include a first conductive portion 61 and a second conductive portion 62 disposed on the first conductive portion 61. The first conductive portion 61 may include polysilicon, and may extend into the base structure 10 to contact the second active area 12. A material of the second conductive portion 62 may include a conductive material such as tungsten (W). The material of the first conductive portion 61 may same as or different from the material of the second conductive portion 62.

The landing pad 18 may be disposed on the cell contact structures 6 for external connection.

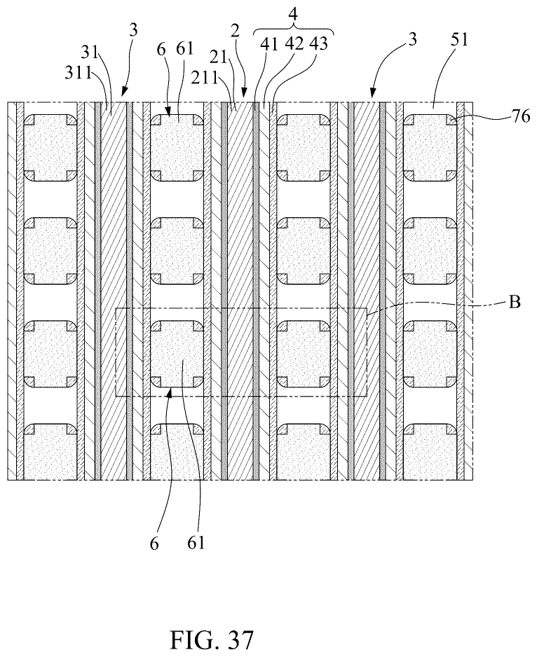

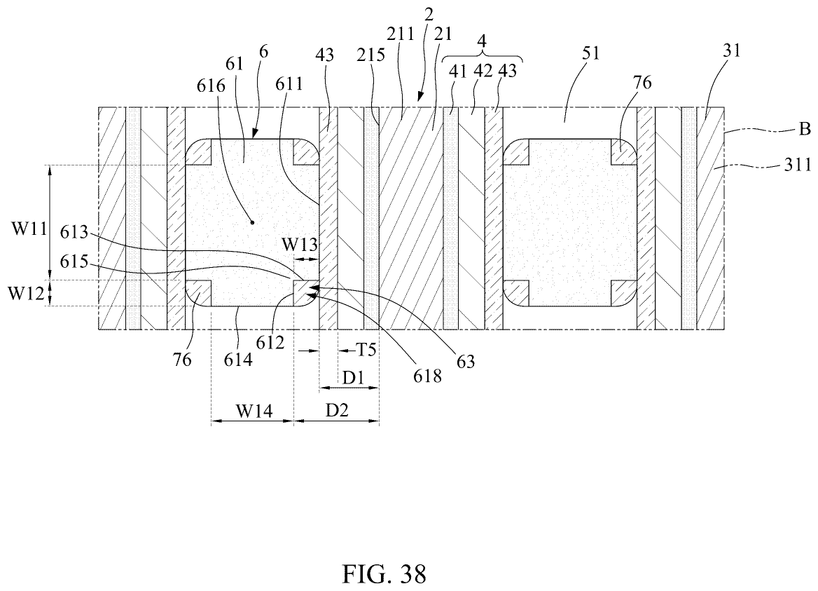

FIG. 37 illustrates a cross-sectional view taken along line II-II of FIG. 36. FIG. 38 illustrates an enlarged view of an area “B” of FIG. 37. The cell contact structure 6 (or the first conductive portion 61) may have a first surface 611, a second surface 612, a third surface 613 and a fourth surface 614. The first surface 611 may have a width W11. The second surface 612 may have a width W12. The third surface 613 may have a width W13. The fourth surface 614 may have a width W14.

The first surface 611 and the second surface 612 may face the first bit line structure 2, and may be substantially parallel with a lateral surface 215 of the main portion 21 of the first bit line structure 2. The first surface 611 of the cell contact structure 6 (or the first conductive portion 61) may be substantially parallel with the second surface 612 of the cell contact structure 6 (or the first conductive portion 61). A first distance D1 (or a horizontal distance or a minimum distance) between the first surface 611 of the cell contact structure 6 (or the first conductive portion 61) and the first bit line structure 2 is different from a second distance D2 (or a horizontal distance or a minimum distance) between the second surface 612 of the cell contact structure 6 (or the first conductive portion 61) and the first bit line structure 2. The first distance D1 may be less than the second distance D2. That is, the first surface 611 of the cell contact structure 6 (or the first conductive portion 61) may be closer to the first bit line structure 2 than the second surface 612 of the cell contact structure 6 (or the first conductive portion 61) is.

The third surface 613 may connect the first surface 611 and the second surface 612. The fourth surface 614 may connect the second surface 612. The third surface 613 and the fourth surface 614 may be substantially perpendicular to the lateral surface 215 of the main portion 21 of the first bit line structure 2. The third surface 613 of the cell contact structure 6 (or the first conductive portion 61) may be substantially parallel with the fourth surface 614 of the cell contact structure 6 (or the first conductive portion 61). The third surface 613 of the cell contact structure 6 (or the first conductive portion 61) may be substantially perpendicular to the first surface 611 of the cell contact structure 6 (or the first conductive portion 61) and the second surface 612 of the cell contact structure 6 (or the first conductive portion 61). The fourth surface 614 of the cell contact structure 6 (or the first conductive portion 61) may be substantially perpendicular to the second surface 612 of the cell contact structure 6 (or the first conductive portion 61).

The width W13 of the third surface 613 of the cell contact structure 6 (or the first conductive portion 61) may be greater than the width W12 of the second surface 612 of the cell contact structure 6 (or the first conductive portion 61). The width W13 of the third surface 613 may be greater than or less than the thickness T5 of the third layer 43 of the spacer 4, the thickness T4 of the second layer 42 of the spacer 4 or the thickness T3 of the first layer 41 of the spacer 4.

In some embodiments, the width W12 of the second surface 612 of the cell contact structure 6 (or the first conductive portion 61) may be 0.07 to 0.23 times, or 0.09 to 0.21 times, or 0.12 to 0.18 times the width W11 of the first surface 611 of the cell contact structure 6 (or the first conductive portion 61). In addition, the width W13 of the third surface 613 of the cell contact structure 6 (or the first conductive portion 61) may be 0.3 to 0.9 times, or 0.4 to 0.8 times, or 0.5 to 0.7 times the width W14 of the fourth surface 614 of the cell contact structure 6 (or the first conductive portion 61).

The third surface 613 of the cell contact structure 6 (or the first conductive portion 61) and the second surface 612 of the cell contact structure 6 (or the first conductive portion 61) may collectively define a groove 63 (or a first groove 618). The groove 63 (or the first groove 618) may be located at a corner 615 of the cell contact structure 6 (or the first conductive portion 61). Thus, the cell contact structure 6 (or the first conductive portion 61) may be substantially in a cross shape from a top view. Each of the four corners 615 of the cell contact structure 6 (or the first conductive portion 61) may define a recess portion, a notch portion or an indentation portion.

A filling material 76 may be disposed in the groove 63 (or the first groove 618). The filling material 76 may include nitride material such as silicon nitride (SiN). In some embodiments, there may be no interface between the third layer 43 and the filling material 76. However, in another embodiments, there may be an interface between the third layer 43 and the filling material 76. The filling material 76 may be substantially in a fan shape (or a sector shape) from a top view. The material of the filling material 76 may be same as or different from the material of the third layer 43 of the spacer 4.

The groove 63 (or the first groove 618) may face the first bit line structure 2. The groove 63 may be configured to reduce the width W11 of the first surface 611 of the cell contact structure 6 (or the first conductive portion 61) most adjacent to the first bit line structure 2. That is, the first surface 611 is most adjacent (or closest) to the first bit line structure 2 among the surfaces 611, 612, 613, 614. The groove 63 may be used to reduce the width W11 of the first surface 611. Thus, the groove 63 (or the first groove 618) may be configured to reduce a parasitic capacitance adjacent to the main portion 21 of the first bit line structure 2, and the signal margin is improved or increased.

The groove 63 (or the first groove 618) may be recessed toward a center 616 of the cell contact structure 6 (or the first conductive portion 61). The fourth surface 614 of the cell contact structure 6 (or the first conductive portion 61) may be substantially perpendicular to the first surface 611 of the cell contact structure 6 (or the first conductive portion 61). The groove 63 (or the first groove 618) may be recessed from the first surface 611 and the fourth surface 614 of the cell contact structure 6 (or the first conductive portion 61).

A lower portion of the landing pad 18 may define a groove 183 (FIG. 35B) continuous with the groove 63 (or the first groove 618) of the cell contact structure 6 (or the first conductive portion 61). Thus, the filling material 76 may be further disposed in the groove 183 of the landing pad 18. The groove 183 of the lower portion of the landing pad 18 may be disposed in four corner of the lower portion of the landing pad 18. Thus, the lower portion of the landing pad 18 may be in a cross shape from a top view.

One aspect of the present disclosure provides a semiconductor structure. The semiconductor structure includes a base structure, a bit line structure and a cell contact structure. The bit line structure is disposed over the base structure. The cell contact structure is disposed around the bit line structure, and has a first surface and a second surface facing the bit line structure. A first distance between the first surface of the cell contact structure and the bit line structure is different from a second distance between the second surface of the cell contact structure and the bit line structure.

Another aspect of the present disclosure provides a semiconductor structure. The semiconductor structure includes a base structure, a bit line structure and a cell contact structure. The bit line structure is disposed over the base structure. The cell contact structure is disposed around the bit line structure, and defines a groove facing the bit line structure. The groove is configured to reduce a width of a surface of the cell contact structure most adjacent to the bit line structure.

Another aspect of the present disclosure provides a method of manufacturing a semiconductor structure. The method includes: providing a base structure, wherein the base structure includes a base portion and at least one active area in the base portion; forming at least one bit line structure over the at least one active area of the base structure; and forming at least one cell contact structure around the at least one bit line structure, wherein the at least one cell contact structure defines a groove facing the at least one bit line structure.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor structure, comprising:
a base structure;
a bit line structure disposed over the base structure; and
a cell contact structure disposed around the bit line structure, and having a first surface and a second surface facing the bit line structure, wherein a first distance between the first surface of the cell contact structure and the bit line structure is different from a second distance between the second surface of the cell contact structure and the bit line structure.

2. The semiconductor structure of claim 1, wherein the base structure includes a base portion and a first active area in the base portion, wherein the bit line structure includes a first bit line structure electrically connected to the first active area through a conductor.

3. The semiconductor structure of claim 2, wherein the base structure further includes a second active area in the base portion, wherein the cell contact structure is electrically connected to the second active area.

4. The semiconductor structure of claim 2, wherein the bit line structure further includes a second bit line structure electrically insulated from the base structure through an insulator.

5. The semiconductor structure of claim 1, further comprising a spacer interposed between the bit line structure and the cell contact structure.

6. The semiconductor structure of claim 5, wherein the spacer include a first layer, a second layer and a third layer, wherein the second layer is interposed between the first layer and the third layer.

7. The semiconductor structure of claim 1, wherein the bit line structure includes a main portion and a cap portion disposed on the main portion.

8. The semiconductor structure of claim 1, further comprising a landing pad disposed on the cell contact structure.

9. The semiconductor structure of claim 1, wherein the first surface of the cell contact structure is substantially parallel with the second surface of the cell contact structure.

10. The semiconductor structure of claim 1, wherein the first surface of the cell contact structure is substantially parallel with a surface of the bit line structure.

11. The semiconductor structure of claim 1, wherein the cell contact structure further has a third surface connecting the first surface and the second surface.

12. The semiconductor structure of claim 11, wherein the third surface of the cell contact structure is substantially perpendicular to the first surface of the cell contact structure.

13. The semiconductor structure of claim 11, wherein a width of the third surface of the cell contact structure is greater than a width of the second surface of the cell contact structure.

14. The semiconductor structure of claim 11, wherein the third surface of the cell contact structure and the second surface of the cell contact structure collectively define a groove.

15. The semiconductor structure of claim 14, wherein the groove is located at a corner of the cell contact structure.

16. The semiconductor structure of claim 14, further comprises a filling material disposed in the groove.

17. The semiconductor structure of claim 16, wherein the filling material is substantially in a fan shape from a top view.

18. The semiconductor structure of claim 17, wherein a material of the filling material is same as a material of a spacer interposed between the bit line structure and the cell contact structure.

19. The semiconductor structure of claim 11, wherein the cell contact structure further has a fourth surface connecting the second surface, wherein the fourth surface is substantially parallel with the third surface.

20. The semiconductor structure of claim 1, wherein a width of the second surface of the cell contact structure is 0.07 to 0.23 times a width of the first surface of the cell contact structure.
